(19) United States
(12) Patent Application Publication
(10) Pub. No.: US 2013/0084524 A1
(43) Pub. Date: Apr. 4, 2013

(54) COMPOSITION FOR FORMING LIQUID IMMERSION UPPER LAYER FILM AND METHOD FOR FORMING RESIST PATTERN

(71) Applicant: JSR CORPORATION, Tokyo (JP)

(72) Inventors: Takahiro HAYAMA, Tokyo (JP); Kazunori KUSABIRAKI, Tokyo (JP); Kiyoshi TANAKA, Tokyo (JP); Motoyuki SHIMA, Tokyo (JP)

(73) Assignee: JSR CORPORATION, Tokyo (JP)

(21) Appl. No.: 13/630,263

(22) Filed: Sep. 28, 2012

(30) Foreign Application Priority Data
Sep. 30, 2011 (JP) 2011-217870
Jul. 25, 2012 (JP) 2012-165033

(51) Int. Cl. G03F 7/004; G03F 7/20

(52) U.S. Cl. 430/270.1; 430/325

(57) ABSTRACT

A composition for forming a liquid immersion upper layer film, includes a first polymer, a second polymer and a solvent. The first polymer includes a first structural unit having a group represented by a following formula (i). In the formula (i), n is an integer of 1 to 3, and R¹ represents a hydrocarbon group having a valency of (n+1) and having 1 to 20 carbon atoms. The second polymer is different from the first polymer.

—R¹OH)ₙ (i)

### CROSS-REFERENCE TO RELATED APPLICATIONS

The present application claims priority under 35 U.S.C. §119 to Japanese Patent Application No. 2011-217870, filed Sep. 30, 2011 and to Japanese Patent Application No. 2012-165033, filed Jul. 25, 2012. The contents of these applications are incorporated herein by reference in their entirety.

### BACKGROUND OF THE INVENTION

1. Field of the Invention

The present invention relates to a composition for forming a liquid immersion upper layer film and a method for forming a resist pattern.

2. Discussion of the Background

In production of semiconductor devices, microfabrication by lithography using a chemically amplified type resist composition has been conventionally performed. Generally, a method for forming a pattern using this microfabrication includes a step of forming a resist film on a substrate, an exposure step of irradiating the resist film through a mask with a radioactive ray such as an ultraviolet ray, a development step of developing the exposed resist film, and a step of etching the substrate using the resulting resist pattern as a protective film.

In this method for forming a pattern, an acid generated on light-exposed sites causes an acid-dissociable group of a polymer in the resist composition to remove, and to change its polarity. The change of its polarity causes the difference of dissolving rate between the light-exposed sites and non-light-exposed sites in a developer solution, resulting in a pattern formation.

In recent years, as a method of forming a finer resist pattern, a utilization of a liquid immersion lithography process has been expanded, in which the process is carried out by filling a space between a lens and a resist film with a liquid immersion medium pure water or fluorine-based inert liquid before exposure. The liquid immersion lithography process has an advantage that numerical aperture (NA) of the lens can increase, even if NA increases, depth of focus is hard to decrease, and high resolving ability can be obtained.

In this method for forming a pattern by liquid immersion lithography process, in order to prevent resist film components from eluting into a liquid immersion medium, a liquid immersion upper layer film is typically provided on the resist film as a protective film. This liquid immersion upper layer film improves anti-eluting properties by avoiding elution of the resist film components due to its water repellency in the exposure step, while in the following development step, the upper layer film is dissolved in the developer solution and removed due to high solubility in the developer solution.

The composition for forming a liquid immersion upper layer film capable of forming the liquid immersion upper layer film has been required to have an improved peel resistance and exposure latitude in a direct contacting site of the liquid immersion upper layer film and the substrate in the peripheral edge of liquid immersion upper layer film, in addition to water repellency, anti-eluting properties, and solubility as described above.

In order to address this requirement, as a technique to improve peel resistance, a liquid immersion upper layer film containing carboxylic acid-based resin is disclosed (See Japanese Unexamined Patent Application, Publication No. 2009-205132).

### SUMMARY OF THE INVENTION

According to one aspect of the present invention, a composition for forming a liquid immersion upper layer film includes a first polymer, a second polymer and a solvent. The first polymer includes a first structural unit having a group represented by a following formula (i).

—R¹OH)ₙ (i)

In the formula (i), n is an integer of 1 to 3, and R¹ represents a hydrocarbon group having a valency of (n+1) and having 1 to 20 carbon atoms. The second polymer is different from the first polymer.

According to another aspect of the present invention, a method for forming a resist pattern includes providing a resist film on a substrate using a resist composition. A liquid immersion upper layer film is provided on the resist film using the composition for forming a liquid immersion upper layer film. The resist film and the liquid immersion upper layer film are exposed through a liquid immersion medium. The resist film and the liquid immersion upper layer film exposed are developed.

### DESCRIPTION OF THE EMBODIMENTS

An aspect of the embodiments of the present invention provides a composition for forming a liquid immersion upper layer film including

(A1) a polymer including a structural unit (1-1) having a group represented by the following formula (i) (hereinafter, may be also referred to as “polymer (A1)”),

(A2) a polymer that is different from the polymer (A1) (hereinafter, may be also referred to as “polymer (A2)”), and

(B) a solvent.

—R¹OH)ₙ (i)

in the formula (1), R¹ represents a hydrocarbon group having a valency of (n+1) and having 1 to 20 carbon atoms; and n is an integer of 1 to 3.

According to the composition for forming a liquid immersion upper layer film, peel resistance and exposure latitude can be achieved in a good balance by including the polymer (A1) having a hydroxyl group. In addition, the composition can provide improved water repellency and anti-eluting properties by containing the polymer (A2). As a result, according to the composition for forming a liquid immersion upper layer film, a liquid immersion upper layer film capable of achieving peel resistance and exposure latitude in a good balance can be formed while meeting characteristics such as water repellency.

A receding contact angle of the polymer (A2) in the form of film on water is preferably greater than that of the polymer (A1). Since the receding contact angle of the polymer (A2) in the form of film on water is greater than that of the polymer (A1), the composition for forming a liquid immersion upper layer film can further improve water repellency against water which is usually used as liquid immersion medium, and anti-eluting properties of the resist film components in water.

The structural unit (I-1) is preferably a structural unit represented by the following formula (1):

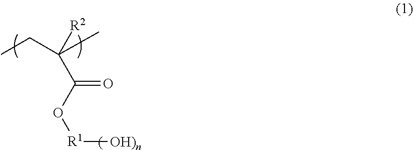

in the formula (1), R² and n are as defined in connection with the above formula (i); and R² represents a hydrogen atom, a methyl group, a fluorine atom or a trifluoromethyl group.

Since the structural unit (I-1) is the specified structural unit, according to the composition for forming a liquid immersion upper layer film, peel resistance and exposure latitude can be achieved in a good balance.

The polymer (A2) preferably contains at least one structural unit selected from the group consisting of a structural unit having a group represented by the following formula (2), and a structural unit having a group represented by the following formula (3).

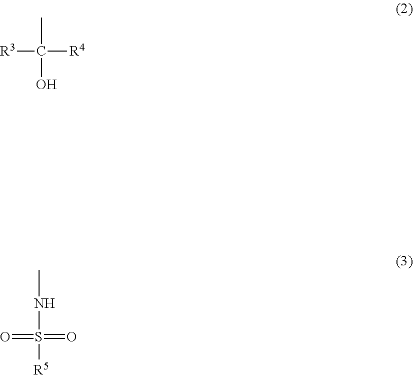

In the formula (2), R³ and R⁴ each represent a hydrogen atom, an alkyl group having 1 to 4 carbon atoms or a fluorinated alkyl group having 1 to 4 carbon atoms, wherein at least any one of R³ and R⁴ represents a fluorinated alkyl group having 1 to 4 carbon atoms. In the formula (3), R⁵ represents a fluorinated alkyl group having 1 to 20 carbon atoms.

Since the polymer (A2) includes the specified structural unit, the composition for forming a liquid immersion upper layer film can further improve water repellency and anti-eluting properties.

The polymer (A2) preferably further includes a structural unit (II-2) represented by the following formula (4):

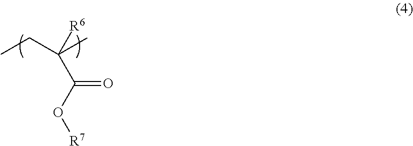

in the formula (4), R⁶ represents a hydrogen atom, a methyl group, a fluorine atom or a trifluoromethyl group; and R⁷ represents a monovalent fluorinated hydrocarbon group having 1 to 12 carbon atoms.

Since the polymer (A2) includes the specified structural unit, the composition for forming a liquid immersion upper layer film can further improve water repellency and anti-eluting properties.

The polymer (A1) preferably further includes at least one structural unit (I-2) selected from the group consisting of a structural unit having a group represented by the following formula (2′), and a structural unit having a group represented by the following formula (3′).

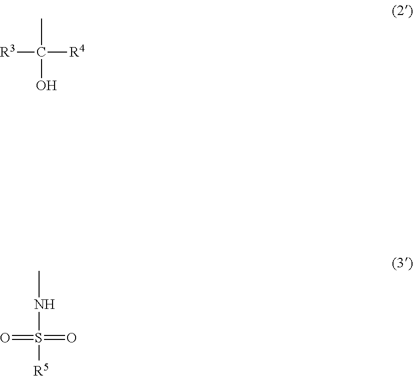

In the formula (2′), R³ and R⁴ are as defined in connection with the above formula (2), and

in the formula (3′), R⁵ is as defined in connection with the above formula (3).)

Since the polymer (A1) includes the specified structural unit, the composition for forming a liquid immersion upper layer film can further improve water repellency and anti-eluting properties.

The polymer (A1) preferably further includes a structural unit (I-3) having a sulpho group. Since the polymer (A1) includes the specified structural unit, the composition for forming a liquid immersion upper layer film can further improve peel resistance.

The solvent (B) preferably contains an ether solvent. Since the solvent (B) contains the ether solvent, the composition for forming a liquid immersion upper layer film can provide an improved coating properties, and can also decrease an intermixing of the resist film and the liquid immersion upper layer film.

One method for forming a resist pattern of the embodiment of the present invention includes

(1) forming a resist film on a substrate using a resist composition;

(2) forming a liquid immersion upper layer film on the resist film using the composition for forming a liquid immersion upper layer film;

(3) exposing the resist film and liquid immersion upper layer film through a liquid immersion medium; and

(4) developing the resist film and the liquid immersion upper layer film exposed.

Since the method for forming a resist pattern includes the specified steps, according to the method for forming a resist pattern, peel resistance and exposure latitude can be achieved in a good balance while meeting characteristics of water repellency, anti-eluting properties and solubility.

It is noted that the receding contact angle of the polymer (A1) and (A2) in the form of film on water are values obtained by spin coating a silicon wafer with a solution containing each polymer to form a film, discharging water through a syringe on the resulting film to form 25 μL of water droplet on the film, withdrawing the syringe from the water droplet, and then re-inserting the syringe in the water droplet, measuring the receding contact angle at a frequency of 1 time per second while suctioning the water droplet through the syringe at a speed of 10 μL/min for 90 sec, and averaging the receding contact angles measured within 20 sec after the measurement was stabilized.

The composition for forming a liquid immersion upper layer film of the embodiment of the present invention and the method for forming a resist pattern can balance peel resistance and exposure latitude while meeting characteristics such as water repellency, anti-eluting properties and solubility. Therefore, the composition for forming a liquid immersion upper layer film and method for forming a resist pattern can be suitably applied to a process of making semiconductor devices having further miniaturized resist patterns. The embodiments will now be described in detail.

### <Composition for Forming a Liquid Immersion Upper Layer Film>

The composition for forming a liquid immersion upper layer film of the embodiment of the present invention includes a polymer (A1), a polymer (A2), and a solvent (B). Additionally, the composition may include any optional component without spoiling the effects of the invention. Now, each component will be described in detail.

### <Polymer (A1)>

The polymer (A1) is a polymer including the structural unit (I-1). Further, the polymer (A1) may include the structural unit (I-2). Further, the polymer (A1) may include the structural unit (I-3). Further, the polymer (A1) may include any other structural units. Also, the polymer (A1) may include two or more of these structural units.

### [Structural Unit (I-1)]

The structural unit (I-1) is a structural unit having a group represented by the above formula (i). Since the polymer (A1) includes the structural unit having a group represented by the above formula (i), according to the composition for forming a liquid immersion upper layer film, a liquid immersion upper layer film capable of achieving peel resistance and exposure latitude in a good balance can be formed while meeting characteristics such as water repellency, anti-eluting properties and solubility.

In the above formula (i), R¹ represents a hydrocarbon group having a valency of (n+1) and having 1 to 20 carbon atoms; and n is an integer of 1 to 3. n is preferably 1 or 2.

Examples of the hydrocarbon group having a valency of (n+1) and having 1 to 20 carbon atoms, represented as R¹, include a linear or branched chain hydrocarbon group having a valency of (n+1) and having 1 to 20 carbon atoms, an alicyclic hydrocarbon group having a valency of (n+1) and having 3 to 20 carbon atoms, an aromatic hydrocarbon group having a valency of (n+1) and having 6 to 20 carbon atoms, or a group in combination with these two or more groups having a valency of (n+1), and the like.

Examples of the linear or branched chain hydrocarbon group having a valency of (n+1) and having 1 to 20 carbon atoms include a group in which n hydrogen atoms are removed from a linear or branched alkyl group having 1 to 20 carbon atoms, and the like.

Examples of the linear or branched alkyl group having 1 to 20 carbon atoms include a methyl group, an ethyl group, a n-propyl group, an i-propyl group, a n-butyl group, a 2-methylpropyl group, a 1-methylpropyl group, a t-butyl group, and the like.

Examples of the alicyclic hydrocarbon group having a valency of (n+1) and having 3 to 20 carbon atoms include a group in which n hydrogen atoms are removed from a monovalent alicyclic hydrocarbon group having 3 to 20 carbon atoms, and the like.

Examples of the monovalent alicyclic hydrocarbon group having 3 to 20 carbon atoms include a cyclopropyl group, a cyclopentyl group, a cyclohexyl group, a norbornyl group, an adamantyl group, and the like.

Examples of the aromatic hydrocarbon group having a valency of (n+1) and having 6 to 20 carbon atoms include a group in which n hydrogen atoms are removed from a monovalent aromatic hydrocarbon group having 6 to 20 carbon atoms, and the like.

Examples of the monovalent aromatic hydrocarbon group having 6 to 20 carbon atoms include a phenyl group, a tolyl group, a naphthyl group, and the like.

Examples of the group in combination with these two or more groups having a valency of (n+1) include a group in combination with these two or more groups exemplified as a linear or branched hydrocarbon group having a valency of (n+1) and having 1 to 20 carbon atoms, an alicyclic hydrocarbon group having a valency of (n+1) and having 3 to 20 carbon atoms, an aromatic hydrocarbon group having a valency of (n+1) and having 6 to 20 carbon atoms, and the like.

The structural unit (I-1) is preferably the structural unit represented by the above formula (1). Since the polymer (A1) includes the structural unit represented by the above formula (1), peel resistance and exposure latitude can be achieved in a good balance.

In the above formula (1), R¹ and n are as defined in connection with the above formula (i); and R² represents a hydrogen atom, a methyl group, a fluorine atom or a trifluoromethyl group.

The hydrocarbon group represented by R¹ is preferably a hydrocarbon group having 1 to 10 carbon atoms, more preferably, a linear or branched chain hydrocarbon group having 1 to 5 carbon atoms, an alicyclic hydrocarbon group having 3 to 8 carbon atoms, or a group in combination with these two or more groups.

A structural unit represented by the following formula is particularly preferred as a structural unit (I-1).

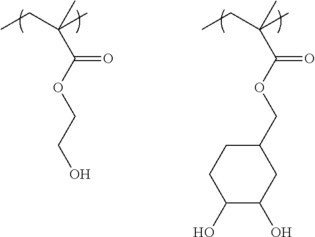

The content of the structural unit (I-1) in total structural units of the polymer (A1) is preferably from 0.1 mol % to 50 mol %, more preferably from 0.5 mol % to 30 mol %. Since the content of the structural unit (I-1) is within the specified range, peel resistance and exposure latitude can be effectively achieved in a good balance.

### [Structural Unit (I-2)]

The structural unit (I-2) is at least one structural unit selected from the group consisting of the structural unit having a group represented by the above formula (2′) and the structural unit having a group represented by the above formula (3′). Since the polymer (A1) includes the structural unit (I-2), the composition for forming a liquid immersion upper layer film can further improve water repellency and anti-eluting properties.

In the above formula (2′), R³ and R⁴ each represent a hydrogen atom, an alkyl group having 1 to 4 carbon atoms or a fluorinated alkyl group having 1 to 4 carbon atoms, wherein at least any one of R³ and R⁴ represents a fluorinated alkyl group having 1 to 4 carbon atoms. In the formula (3′), R⁵ represents a fluorinated alkyl group having 1 to 20 carbon atoms.

The alkyl group having 1 to 4 carbon atoms represented by R³ and R⁴ may be linear or branched, and includes a methyl group, an ethyl group, an n-propyl group, an i-propyl group, and the like.

The fluorinated alkyl group having 1 to 4 carbon atoms represented by R³ and R⁴ is a group in which at least one of hydrogen atoms in an alkyl group having 1 to 4 carbon atoms is substituted with a fluorine atom. As the alkyl group having 1 to 4 carbon atoms the alkyl group having 1 to 4 carbon atoms represented by R³ and R⁴ as exemplified above can be applied.

The fluorinated alkyl group having 1 to 20 carbon atoms represented by R⁵ is a group in which at least one of hydrogen atoms in an alkyl group having 1 to 20 carbon atoms is substituted by a fluorine atom. The alkyl group having 1 to 20 carbon atoms can be linear or branched, and includes a methyl group, an ethyl group, an n-propyl group, an i-propyl group, and the like.

The fluorinated alkyl group having 1 to 4 carbon atoms represented by R³ and R⁴ is preferably a trifluoromethyl group.

The structural unit (I-2) having the group represented by the above formula (2′) and the structural unit (I-2) having the group represented by the above formula (3′) can be exemplified as a structural unit represented by the following formula (2′-1) and a structural unit represented by the following formula (3′-1), respectively.

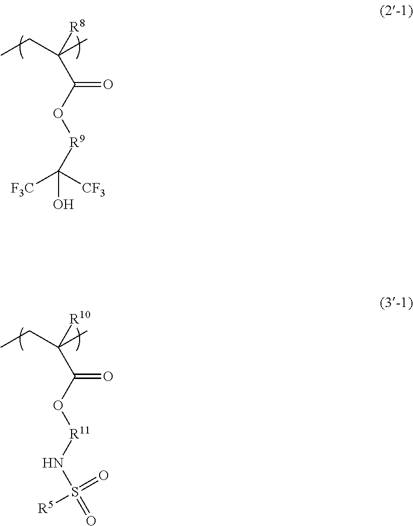

In the above formulae (2′-1) and (3′-1), R⁸ and R¹⁰ each independently represent a hydrogen atom, a methyl group, a fluorine atom or a trifluoromethyl group. In the formula (2′-1), R⁹ represents a bivalent linking group. In the formula (3′-1), R¹¹ represents a bivalent linking group. R⁵ is as defined in connection with the above formula (3).

Examples of the bivalent linking group represented by R⁹ include a linear or branched bivalent chain hydrocarbon group having 1 to 6 carbon atoms, a bivalent alicyclic hydrocarbon group having 4 to 12 carbon atoms, or a group in combination with these groups, and the like.

Examples of the linear or branched bivalent chain hydrocarbon group having 1 to 6 carbon atoms include a methylene group, an ethylene group, a 1,3-propylene group, a 1,2-propylene group, a 1,1-propylene group, a 2,2-propylene group, a tetramethylene group, a pentamethylene group, a hexamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, and the like.

Examples of the bivalent alicyclic hydrocarbon group having 4 to 12 carbon atoms include a monocyclic hydrocarbon group such as a cyclobutylene group, a cyclopentylene group, a cyclohexylene group and a cyclooctylene group; a polycyclic hydrocarbon group such as a norbornylene group and an adamantylene group, and the like.

For example, the group exemplified as the bivalent linking group represented by R⁹ can be applied as a bivalent linking group represented by R¹¹.

Examples of the structural unit represented by the above formula (2′-1) include a structural unit represented by any one of the following formulae (2′-1-1) to (2′-1-8), and the like.

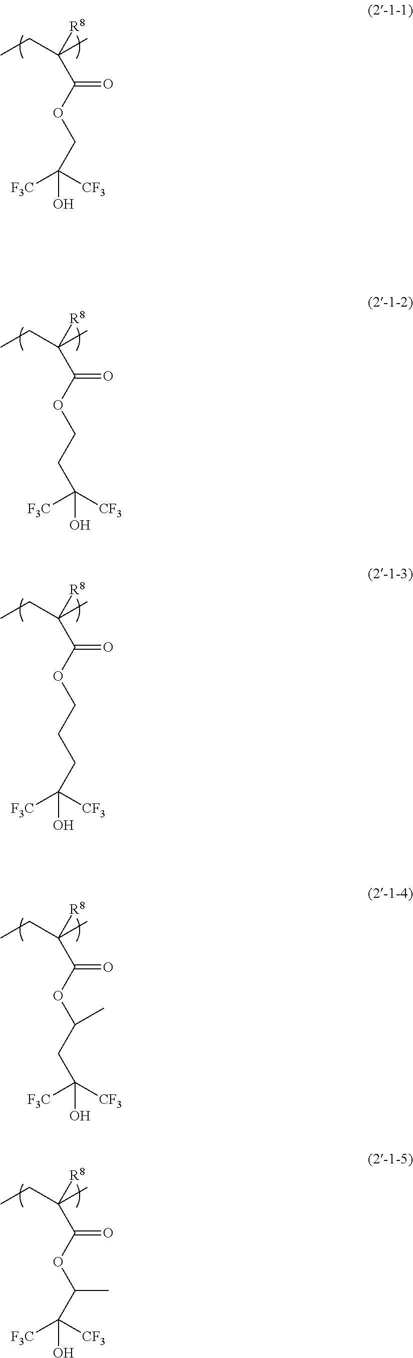

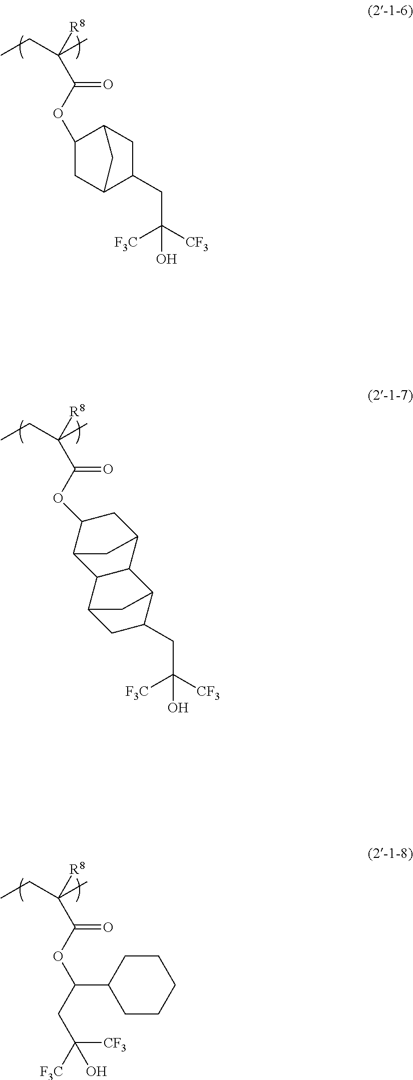

In the above formulae (2′-1-1) to (2′-1-8), R⁸ is as defined in connection with the above formula (2′-1). Of these, the structural unit represented by any one of formulae (2′-1-4) and (2′-1-8) is preferred.

Examples of the structural unit represented by the above formula (3′-1) include a structural unit represented by any one of the following formulae (3′-1-1) to (3′-1-3), and the like.

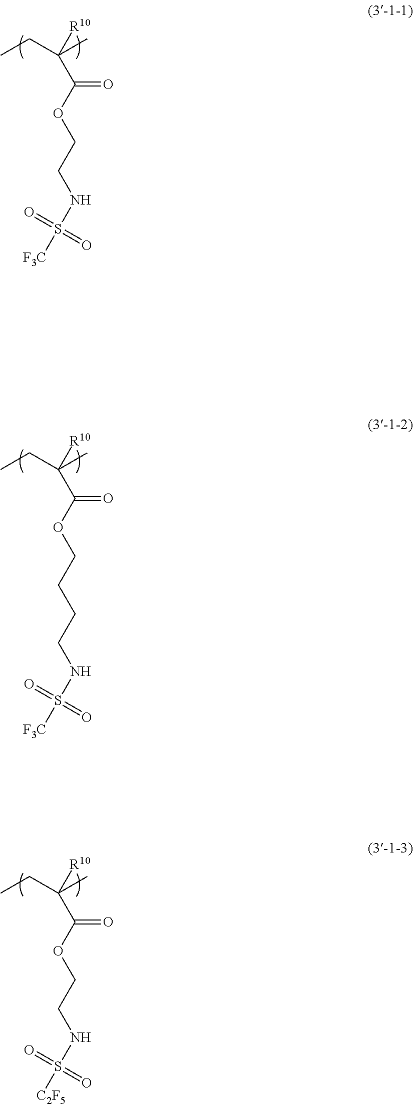

In the above formulae (3′-1-1) to (3′-1-3), R¹⁰ is as defined in connection with the above formula (3′-1). Of these, the structural unit represented by formula (3′-1-1) is preferred.

The content of the structural unit (I-2) in total structural units of the polymer (A1) is preferably from 20 mol % to 98 mol %, more preferably from 35 mol % to 95 mol %, more further preferably from 50 mol % to 90 mol %. Since the content of the structural unit (I-2) is within the specified range, the polymer can improve water repellency and anti-eluting properties effectively.

### [Structural Unit (I-3)]

The structural unit (I-3) is a structural unit having a sulfo group. Since the polymer (A1) further includes the specified structural unit (I-3), the composition for forming a liquid immersion upper layer film can further improve peel resistance.

Examples of the structural unit (I-3) include a structural unit represented by the following formula (5), and the like.

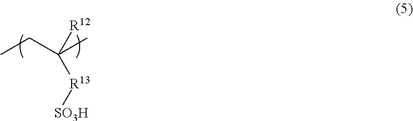

In the above formula (5), R¹² represents a hydrogen atom, a methyl group, a fluorine atom or a trifluoromethyl group. R¹³ represents a single bond, an oxygen atom, a sulfur atom, a linear or branched bivalent chain hydrocarbon group having 1 to 6 carbon atoms, a bivalent alicyclic hydrocarbon group having 4 to 12 carbon atoms, a bivalent aromatic hydrocarbon group having 6 to 12 carbon atoms or —C(═O)—X—Y-group. X represents an oxygen atom, a sulfur atom or a NH group. Y represents a single bond, a linear or branched bivalent hydrocarbon group having 1 to 6 carbon atoms, a bivalent alicyclic hydrocarbon group having 4 to 12 carbon atoms or a bivalent aromatic hydrocarbon group having 6 to 12 carbon atoms.

Examples of the linear or branched bivalent chain hydrocarbon group having 1 to 6 carbon atoms, represented by R¹³ and Y, include a methylene group, an ethylene group, a 1,3-propylene group, a 1,2-propylene group, a 1,1-propylene group, a 2,2-propylene group, a tetramethylene group, a pentamethylene group, a hexamethylene group, a 1-methyl-1,3-propylene group, a 2-methyl-1,3-propylene group, a 2-methyl-1,2-propylene group, a 1-methyl-1,4-butylene group, a 2-methyl-1,4-butylene group, and the like.

Examples of the bivalent alicyclic hydrocarbon group having 4 to 12 carbon atoms, represented by R¹³ and Y, include a monocyclic hydrocarbon group such as a cyclobutylene group, a cyclopentylene group, and a cyclooctylene group; a polycyclic hydrocarbon group, such as a norbornylene group and an adamantylene group, and the like.

Examples of the bivalent aromatic hydrocarbon group having 6 to 12 carbon atoms, represented by R¹³ and Y, include an arylene group such as a phenylene group and a tolylene group. Also, the alicyclic hydrocarbon group and the aromatic hydrocarbon group are not necessarily composed of a ring structure only, and they may contain a linear structure in the part of them.

The structural unit (I-3) is preferably a structural unit represented by any one of the following formulae (5-1) to (5-5).

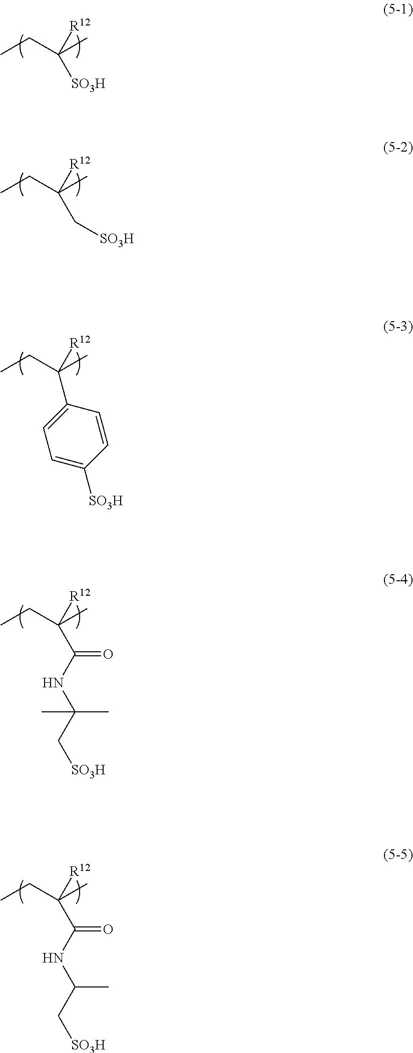

In the above formulae (5-1) to (5-5), R¹² is as defined in connection with the above formula (5). Of these, (5-1) and (5-5) are preferred.

The content of the structural unit (I-3) in total structural units of the polymer (A1) is preferably from 0.1 mol % to 20 mol %, more preferably from 1 mol % to 15 mol %. Since the content of the structural unit (I-3) is within the specified range, the polymer can improve peel resistance effectively.

### [Other Structural Units]

The polymer (A1) may include any other structural units other than the structural units (I-1) to (I-3) without impairing the effects of the invention.

The receding contact angle of the polymer (A1) in the form of film on water is preferably no greater than 70°, more preferably no greater than 68°, and more further preferably no greater than 63°.

### <Polymer (A2)>

The polymer (A2) is a polymer that is different from the polymer (A1). While the polymer (A2) is not particularly limited so as to be different from the polymer (A1), the receding contact angle of the polymer (A2) in the form of film on water is preferably greater than that of the polymer (A1). In this case, the difference of the receding contact angle between the polymer (A2) and (A1) is preferably no less than 3°, more preferably no less than 5°, and particularly preferably no less than 10°.

Also, the receding contact angle of the polymer (A2) in the form of film on water is preferably no less than 73°, more preferably no less than 75°, and further preferably no less than 80°.

Since the polymer (A2) is the specified polymer, the composition for forming a liquid immersion upper layer film can further improve water repellency against water which is usually used as a liquid immersion medium, and anti-eluting properties of the resist film component in water.

Preferably, the polymer (A2) is a polymer including the structural unit (II-1). Also, the polymer (A2) may include the structural unit (II-2). Also, the polymer (A2) may include any other structural unit. Also, the polymer (A2) may include two or more of these structural units.

### [Structural Unit (II-1)]

The structural unit (II-1) is at least one structural unit selected from the group consisting of the structural unit having a group represented by the above formula (2) and the structural unit having a group represented by the above formula (3). Since the polymer (A2) includes the structural unit (II-1), the composition for forming a liquid immersion upper layer film can further improve water repellency and anti-eluting properties. Also, the structural unit having a group represented by the above formula (2) and the structural unit having a group represented by the above formula (3) are similar to the structural unit having a group represented by the above formula (2′) and structural unit having a group represented by the above formula (3′) respectively, as described in the structural unit (I-2).

The content of the structural unit (II-1) in total structural units of the polymer (A2) is preferably from 5 mol % to 100 mol %, more preferably from 20 mol % to 99 mol %. Since the content of the structural unit (II-1) is within the specified range, the polymer can improve water repellency and anti-eluting properties effectively.

### [Structural Unit (II-2)]

The structural unit (II-2) is a structural unit represented by the above formula (4). Since the polymer (A2) includes the specified structural unit, the composition for forming a liquid immersion upper layer film can further improve water repellency and anti-eluting properties.

In the above formula (4), R⁶ represents a hydrogen atom, a methyl group, a fluorine atom or a trifluoromethyl group. R⁷ represents a monovalent fluorinated hydrocarbon group having 1 to 12 carbon atoms.

The monovalent fluorinated hydrocarbon group having 1 to 12 carbon atoms, represented by R⁷, is a group in which at least one of hydrogen atoms in a monovalent hydrocarbon group having 1 to 12 carbon atoms is substituted with a fluorine atom.

Examples of the monovalent hydrocarbon group having 1 to 12 carbon atoms include a linear or branched alkyl group having 1 to 12 carbon atoms, a monovalent alicyclic hydrocarbon group having 3 to 12 carbon atoms or a group in combination with these two or more groups, and the like.

Examples of the linear or branched alkyl group having 1 to 12 carbon atoms include a methyl group, an ethyl group, a n-propyl group, an i-propyl group, an n-butyl group, a 2-methylpropyl group, a 1-methylpropyl group, a t-butyl group, and the like.

Examples of the monovalent alicyclic hydrocarbon group having 3 to 12 carbon atoms include a cyclopropyl group, a cyclopentyl group, a cyclohexyl group, a norbornyl group, an adamantyl group, and the like.

Preferably, the structural unit (II-2) is the structural unit represented by any one of the following formulae (4-1) to (4-6).

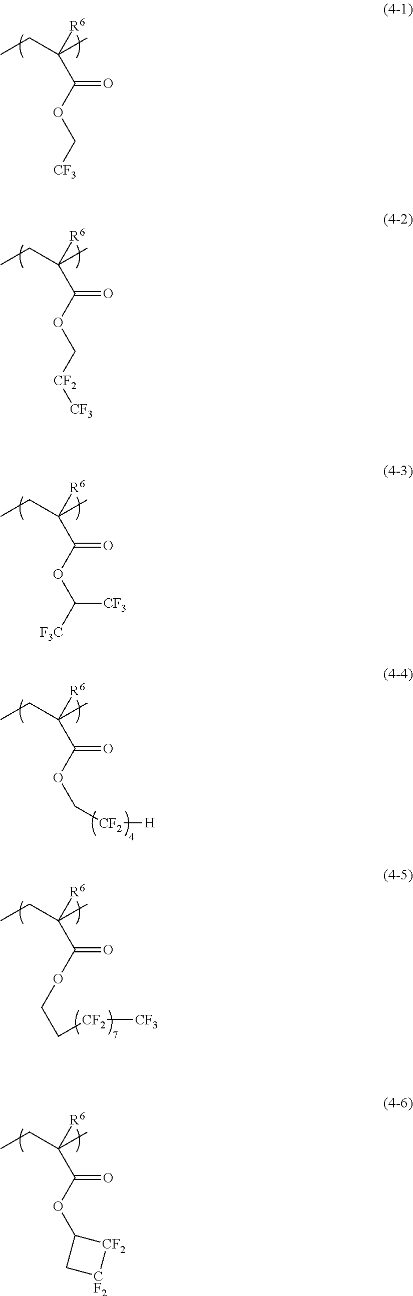

In the above formulae, R⁶ is as defined in connection with the formula (4).

The content of the structural unit (II-2) in total structural units of the polymer (A2) is preferably from 1 mol % to 90 mol %, more preferably from 10 mol % to 80 mol %. Since the content of the structural unit (II-2) is within the specified range, the polymer can improve can water repellency and anti-eluting properties effectively.

### [Other Structural Unit]

The polymer (A2) may include any other structural unit other than the structural units (II-1) and (II-2) without spoiling the effects of the invention. Examples of the other structural unit include a structural unit having a carboxy group, a structural unit having a sulfo group explained as the structural unit (I-3) in the polymer (A1), and the like.

### [Structural Unit Having a Carboxy Group]

Examples of the structural unit having a carboxy group include a structural unit derived from (meth)acrylic acid, crotonic acid, angelic acid, or tiglic acid, and the like.

The content of the structural unit having a carboxy group in total structural units of the polymer (A2) is preferably from 0 mol % to 50 mol %, more preferably from 10 mol % to 30 mol %. Since the content of the structural unit having a carboxy group is within the specified range, the polymer can improve peel resistance effectively.

### [Structural Unit [I-3]]

The content of the structural unit (I-3) in total structural units of the polymer (A2) is preferably from 0.1 mol % to 20 mol %, more preferably from 1 mol % to 15 mol %. Since the content of the structural unit (I-3) in the polymer (A2) is within the specified range, the polymer can improve peel resistance effectively.

The content of the polymer (A2) is preferably from 0.5 parts by mass to 4,000 parts by mass, more preferably from 1 part by mass to 2,000 parts by mass based on the 100 parts by mass of the polymer (A1). Since the content of the polymer (A2) is within the range, the polymer can improve water repellency and anti-eluting properties effectively.

### <Method for Synthesizing Each Polymer>

As a method for synthesizing each polymer each polymer can be synthesized by polymerizing any monomer corresponding to the specified structural unit with a radical polymerization initiator in a suitable solvent.

Examples of the polymerization initiator include 2,2′-azobisisobutyronitrile, 2,2′-azobis(4-methoxy-2,4-dimethylvaleronitrile), 2,2′-azobis(2-cyclopropylpropionitrile), 2,2′-azobis(2,4-dimethylvaleronitrile), 2,2′-azobis(2-methylpropionitrile), dimethyl 2,2-azobisisobutyrate, and the like. These initiators may be used either alone or in combination of two or more thereof.

The solvent for polymerization is not particularly limited so as to be any solvent other than solvents inhibiting polymerization (nitrobenzene having a polymerization inhibiting effect, a mercapto compound having a chain transferring effect, and the like). In the case of polymerizing in the presence of a crosslinking agent and a crosslinking catalyst, the type of the solvent is not particularly limited. Examples of the solvent for polymerization include an alcohol type solvent, a ketone type solvent, an amide type solvent, an ester-lactone type solvent, a nitrile type solvent and mixed solvent thereof, and the like. These solvents for polymerization may be used either alone or in combination of two or more thereof.

Each polymer obtained from polymerizing reaction can be recycled by liquid-liquid extraction or reprecipitation method. Also, other than liquid-liquid extraction or reprecipitation method, the polymer can be recovered by removing low molecule components with operations such as phase separation, column chromatography, and ultrafiltration.

The reaction temperature in these methods for synthesizing the polymers are suitably determined depending on monomers to provide each structural unit, the type of polymerization initiator to be used, and the like.

The weight average molecular weight (Mw) of each polymer in terms of polystyrene equivalent on gel permeation chromatography (GPC) is preferably from 1,000 to 100,000 and more preferably from 3,000 to 50,000. When the Mw of the polymer is less than 1,000, an intermixing of the liquid immersion upper layer film and the resist film may tend to occur easily. While if the Mw is over 100,000, each polymer may be hard to dissolve in the solvent. Also, the ratio (Mw/Mn) of the Mw to the number average molecular weight (Mn) in terms of polystyrene equivalent on GPC is preferably 1 to 5, more preferably 1 to 3.

It is to be noted that the Mw and Mn as used herein is measured by GPC in an analytical condition using GPC columns (G2000HXL×2, G3000HXL×1, G4000HXL×1) from Tosoh Corporation, monodispersed polystyrene as a standard reference, and tetrahydrofuran as an elution solvent at a flow rate of 1.0 mL/min and a column temperature of 40° C.

### <Solvent (B)>

The solvent (B) is a solvent to dissolve uniformly each component such as polymer (A1) and polymer (A2). Also, the solvent (B) may be used either alone or in combination of two or more thereof.

The solvent (B) is exemplified by an alcohol type solvent, an ether type solvent, a hydrocarbon type solvent, a ketone type solvent, an ester type solvent, water, and the like.

Examples of the alcohol type solvent include monohydric alcohols such as butanol, pentanol and 4-methyl-2-pentanol; polyhydric alcohols such as ethylene glycol and propylene glycol, and the like.

Examples of the ether solvent include alkyl ethers of a polyhydric alcohol such as ethylene glycol monomethyl ether, ethylene glycol monoethyl ether, ethylene glycol dimethyl ether, ethylene glycol methylethyl ether, ethylene glycol diethyl ether and diethylene glycol dimethyl ether; alkyl ether acetates of a polyhydric alcohol such as ethylene glycol monomethyl ether acetate, ethylene glycol monoethyl ether acetate, diethylene glycol monomethyl ether acetate and diethylene glycol monoethyl ether acetate; aliphatic ethers such as diethyl ether, dipropyl ether, dibutyl ether, butylmethyl ether, butylethyl ether, diisoamyl ether, hexylmethyl ether, octylmethyl ether, cyclopentyl methyl ether and dicyclopentyl ether; aliphatic-aromatic ethers such as anisole and phenylethyl ether; cyclic ethers such as tetrahydrofuran, tetrahydropyran and dioxane, and the like.

Examples of the hydrocarbon solvent include higher hydrocarbons such as decane, dodecene and undecane.

Examples of the ketone solvent include acetone, methyl ethyl ketone, methyl n-propyl ketone, methyl n-butyl ketone, diethyl ketone, methyl iso-butyl ketone, methyl n-pentyl ketone, ethyl n-butyl ketone, methyl n-hexyl ketone, di-iso-butyl ketone, trimethylnonanone, cyclopentanone, cyclohexanone, cycloheptanone, cyclooctanone, methyl cyclohexanone, 2,4-pentanedione, acetonyl acetone, diacetone alcohol, acetophenone, and the like.

Examples of the ester solvent include diethyl carbonate, propylene carbonate, methyl acetate, ethyl acetate, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, diethyl phthalate, and the like.

Of these, an alcohol solvent, an ether solvent and a hydrocarbon solvent are preferred, and an alcohol solvent and an ether solvent are more preferred. Of these, an ether solvent is further preferred because the solvent can decrease the applied amount of the composition for forming a liquid immersion upper layer film by decreasing the viscosity of the composition, resulting in a reduced cost.

Also, the alcohol solvent is preferably monohydric alcohols, and the ether solvent is preferably aliphatic ethers, cyclic ethers, alkyl ethers of polyhydric alcohols, alkyl ether acetates of polyhydric alcohols, more preferably a solvent containing at least one of monohydric alcohols having 4 to 10 carbon atoms and aliphatic ethers including an alkyl chain having 4 to 10 carbon atoms, particularly preferably a solvent containing 4-methyl-2-pentanol and diisoamyl ether.

When monohydric alcohols having 4 to 10 carbon atoms and aliphatic ethers including an alkyl chain having 4 to 10 carbon atoms is included as the solvent (B), the mix ratio (mass) of monohydric alcohols having 4 to 10 carbon atoms to aliphatic ethers including an alkyl chain having 4 to 10 carbon atoms is preferably 1:99 to 90:10, more preferably 2:98 to 70:30, further preferably 5:95 to 60:40 and particularly preferably 10:90 to 50:50.

### <Optional Components>

The composition for forming a liquid immersion upper layer film can include any optional components other than the polymer (A1), the polymer (A2) and the solvent (B) without impairing the effects of the invention. Each optional component can be used either alone or in combination of two or more thereof. Also, the blended amount of each optional component can be suitably determined depending on the application.

Examples of the optional component include a surfactant. Examples of the surfactant include commercially available fluorochemical surfactants, such as the trade name BM-1000 and BM-1100 (manufactured by BM Chemie), MEGAFAC F142D, MEGAFAC F172, MEGAFAC F173, MEGAFAC F183 (manufactured by Dainippon Ink And Chemicals, Incorporated). The content of the surfactant is preferably no greater than 5 parts by mass based on the 100 parts by mass of the polymer (A).

### <Method for Preparing Composition for Forming a Liquid Immersion Upper Layer Film>

The composition for forming a liquid immersion upper layer film can be prepared by mixing a certain ratio of the polymer (A1), the polymer (A2), and the solvent (B), and the like.

### <Method for Forming a Resist Pattern>

The method for forming a resist pattern of the embodiment of the present invention includes:

(1) forming a resist film on a substrate using a resist composition;

(2) forming a liquid immersion upper layer film on the resist film using the composition for forming a liquid immersion upper layer film;

(3) exposing the resist film and liquid immersion upper layer film through a liquid immersion medium; and

(4) developing the resist film and the liquid immersion upper layer film exposed.

Since the method for forming a resist pattern includes the specified steps, according to the method for forming a resist pattern, peel resistance and exposure latitude can be achieved in a good balance while meeting characteristics of water repellency, anti-eluting properties and solubility. Next, each step will be described.

### [Step (1)]

This step is a step of forming a resist film on a substrate using a resist composition. Examples of the substrate include silicon wafer.

Examples of the resist composition include a positive type or negative type of chemically amplified type of resist composition containing an acid generating agent, a positive type of resist composition containing an alkali-soluble resin and a quinone diazide-based photosensitizing agent, a negative type resist composition containing an alkali-soluble resin and a crosslinking agent, and the like. Also, some commercially available resist composition can be used as the resist composition. The method for forming resist films is preferably applying method well known method such as spin coating. Also, when the resist composition is applied, the applied amount of the resist composition is adjusted so as to form the resist film having a desired film thickness. Also, after applying the resist composition on the substrate, the film may be prebaked (hereinafter, may be also referred to as “PB”) in order to allow a solvent to be volatilized.

### [Step (2)]

This step is a step of forming a liquid immersion upper layer film on the resist film using the composition for forming a liquid immersion upper layer film.

In this step baking is preferred after applying the composition for forming a liquid immersion upper layer film. Since baking causes the liquid immersion medium not to contact with resist film directly, the lithography performance of the resist film can be prevented effectively from decreasing due to penetration of the liquid immersion medium to the resist film, and can be prevented effectively from contaminating the lens of the projection exposure system with the eluted components from the resist film to the liquid immersion medium. The method for forming the liquid immersion upper layer film can adopt any method similar to the method for forming the resist film, provided that the composition for forming a liquid immersion upper layer film is used instead of the resist composition.

### [Step (3)]

This step is a step of irradiating the resist film and the liquid immersion upper layer film by interposing the liquid immersion medium between the liquid immersion upper layer film and a lens with radioactive ray, and exposing the resist film and the liquid immersion upper layer film.

As the liquid immersion medium, any liquid having a higher refractive index than air is typically used. Specifically, water is preferably used, more preferably, pure water is used. With interposing the liquid immersion medium between the liquid immersion upper layer film and the lens, that is, filling a space between a lens and the liquid immersion upper layer film with liquid immersion medium, radioactive ray is irradiated from the exposure system, and the resist film and the liquid immersion upper layer film are exposed to the radioactive ray through a mask having a predetermined pattern.

Examples of the radioactive ray include, visible light rays; ultraviolet rays such as a g ray and an i ray; far ultraviolet rays such as an excimer laser beam; an X ray; electron beams, and the like. Of these, an ArF excimer laser beam (wavelength of 193 nm) and a KrF excimer laser beam (wavelength of 248 nm) are preferred. Also, the condition of irradiating radioactive ray and the like can be suitably determined depending on the resist composition, the composition for forming a liquid immersion upper layer film, and the like.

### [Step (4)]

This step is a step of developing the exposed resist film and the exposed liquid immersion upper layer film with a developer solution to form a resist pattern. Since the liquid immersion upper layer film is formed by the composition for forming a liquid immersion upper layer film, the liquid immersion upper layer film can be easily removed with the developer solution, whereby specified step for removing the liquid immersion upper layer film is not required.

The developer solution is preferably an alkaline solution dissolving at least one of alkaline compounds including sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethyl ethanolamine, triethanolamine, tetraalkylammonium hydroxides (for example, tetramethylammonium hydroxide (TMAH), tetraethylammonium hydroxide, and the like), pyrrole, piperidine, choline, 1,8-diazabicyclo-[5.4.0]-7-undecene, 1,5-diazabicyclo-[4.3.0]-5-nonane. Of these, an aqueous solution of tetraalkylammonium hydroxides is more preferred. Also, suitable amount of a water soluble organic solvent including an alcohol methanol, ethanol, or a surfactant can be added to this developer solution.

Also, in order to improve the resolution of the resist film, baking is preferred after exposure and before development. While the temperature for baking can be suitably determined depending on the resist composition to be used, the composition for forming a liquid immersion upper layer film, and the like, the temperature is preferably from 30 to 200° C., more preferably from 50 to 150° C.

### EXAMPLES

Next, while the present invention will be described by way of Examples in further detail, the present invention is not limited to these Examples.

Also, the receding contact angle of the polymer (A1) and the polymer (A2) in the form of film on water was measured according to the following method.

### <Method for Measuring the Receding Contact Angle of the Polymer (A1) and the Polymer (A2)>

After each polymer was dissolved in propylene glycol monomethyl ether, the solution was spin coated on a silicon wafer, PB was carried out at 90° C. for 60 sec to form a liquid immersion upper layer film having a film thickness of 30 nm. Thereafter, the wafer was placed on a receding contact angle measuring apparatus (DSA-10, manufactured by KRUS), discharged water through a syringe on the wafer to form 25 μL of water droplet on the wafer, withdrew the syringe from the water droplet, and then re-inserted the syringe in the water droplet, and measured the receding contact angle at a frequency of 1 time per a second while suctioning the water droplet through the syringe at a speed of 10 μL/min for 90 sec. Then, the receding contact angles measured within 20 sec after the measurement was stabilized were averaged, and the average was regarded as the receding contact angle.

Additionally, ¹³C-NMR analysis for measuring the content (mol %) of each structural unit in each polymer was used a nuclear magnetic resonance apparatus (JNM-ECX400, manufactured by JEOL, Ltd.).

### <Synthesis of Each Polymer>

Each polymer was synthesized by using each monomer represented by the following formulae (M-1) to (M-10).

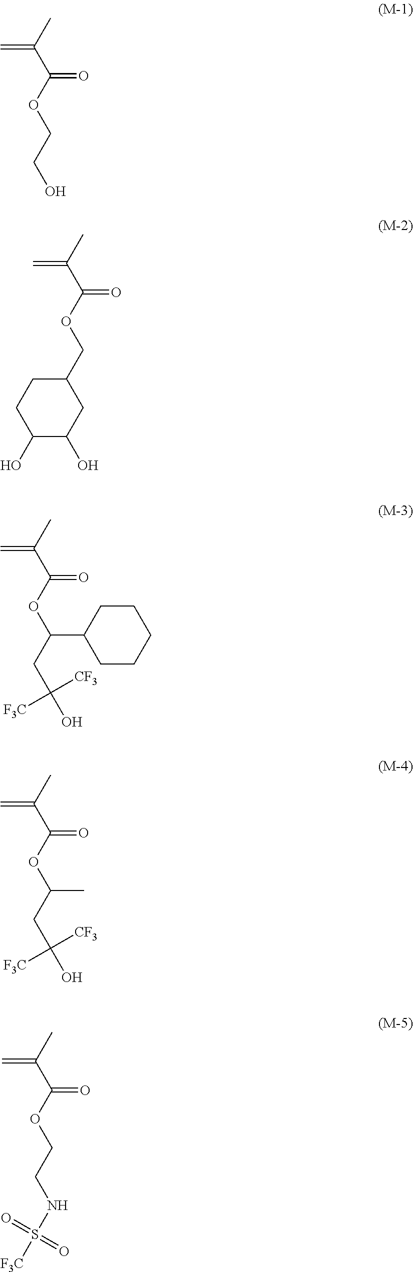

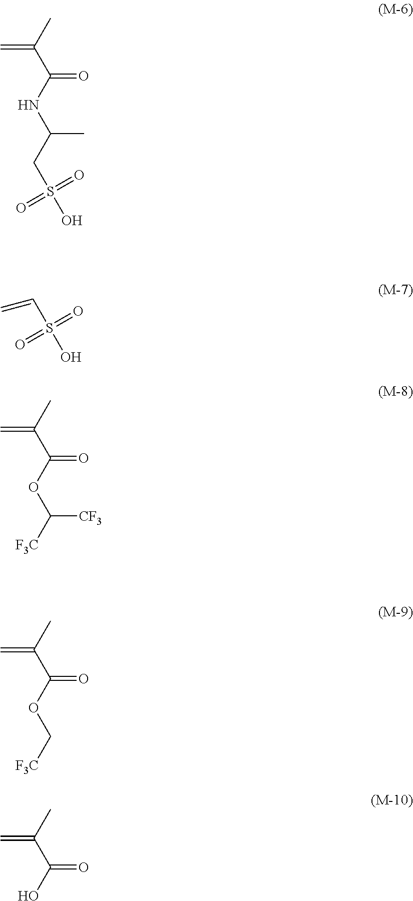

### Synthesis Example 1

### Synthesis of (A1-1)

A monomer solution was prepared by dissolving 0.37 g (5 mol %) of (M-1), 19.39 g (93 mol %) of (M-3), 0.24 g (2 mol %) of (M-6), and 1.33 g of 2,2′-azobis-(2-methyl methyl propionate) as a polymerization initiator in 20.00 g of isopropanol.

Then, to 200 mL three-necked flask equipped with a thermometer and a dropping funnel was charged 50 g of isopropanol, and purged with nitrogen for 30 min. After the nitrogen purge, the content in the flask was heated to 80° C. while stirring with a magnetic stirrer.

After that, using the dropping funnel, the prepared monomer solution was added dropwise for 3 hours. After completing the dropwise adding, the reaction was performed for further 3 hours. Thereafter, the reaction was cooled below 30° C. to obtain a polymer liquid.

After the resulting polymer liquid was concentrated to 60 g, the liquid was transferred to a separatory funnel. To the separatory funnel was charged 150 g of n-heptane, and purified by separation. After the separation, its underlayer liquid was recovered. The liquid was purified by separation by adding the recovered underlayer liquid to 45 g of 4-methyl-2-pentanol and 95 g of water. After the separation, its upper layer liquid was recovered. The recovered upper layer liquid was replaced with 4-methyl-2-pentanol to obtain a solution containing a polymer (A1-1). The Mw of the resulting polymer (A1-1) was 10,000, the ratio Mw/Mn is 1.6, and yield was 50%. The result of ¹³C-NMR analysis showed that the content of the structural unit derived (M-1), (M-3), and (M-6) was 5 mol %, 93 mol %, and 2 mol %, respectively.

### Synthesis Examples 2 to 11

### Synthesis of (A1-2) to (A2-5)

Each polymer was synthesized by operating similar to Synthesis Example 1, provided that the type and the amount of blended monomers were as described in Table 1. The receding contact angles, the Mw and the Mw/Mn of each polymer are shown in Table 1. It is to be noted that “-” in Table 1 shows the corresponding monomer was not blended.

TABLE 1

| | | | | Monomer for | | | | | | Monomer for | | | | |
|---|---|---|---|---|---|---|---|---|---|---|---|---|---|---|
| | | Monomer for | | structural | | Monomer for | | Monomer for | | other | | | | |
| | | structural | | unit (I-2) or | | structural | | structural | | structural | | | | |
| | | unit (I-1) | | (II-1) | | unit (I-3) | | unit (II-2) | | unit | | Receding | | |
| | | | amount | | amount | | amount | | amount | | amount | contact | | |
| | | | used | | used | | used | | used | | used | angle | | |
| | | type | (mol %) | type | (mol %) | type | (mol %) | type | (mol %) | type | (mol %) | (°) | Mw | Mw/Mn |
| Synthesis Example 1 | A1-1 | M-1 | 5 | M-3 | 93 | M-6 | 2 | — | — | — | — | 62 | 10,000 | 1.6 |
| Synthesis Example 2 | A1-2 | M-1 | 10 | M-4 | 88 | M-7 | 2 | — | — | — | — | 60 | 11,000 | 1.65 |
| Synthesis Example 3 | A1-3 | M-1 | 20 | M-5 | 78 | M-6 | 2 | — | — | — | — | 57 | 9,500 | 1.5 |
| Synthesis Example 4 | A1-4 | M-2 | 5 | M-3 | 93 | M-6 | 2 | — | — | — | — | 60 | 9,000 | 1.55 |
| Synthesis Example 5 | A1-5 | M-2 | 10 | M-4 | 88 | M-7 | 2 | — | — | — | — | 58 | 12,000 | 1.65 |
| Synthesis Example 6 | A1-6 | M-2 | 20 | M-5 | 78 | M-6 | 2 | — | — | — | — | 55 | 10,000 | 1.7 |
| Synthesis Example 7 | A2-1 | — | — | M-3 | 60 | — | — | M-8 | 40 | — | — | 80 | 10,000 | 1.6 |
| Synthesis Example 8 | A2-2 | — | — | M-4 | 50 | — | — | M-9 | 50 | — | — | 80 | 9,500 | 1.55 |
| Synthesis Example 9 | A2-3 | — | — | M-5 | 30 | — | — | M-8 | 70 | — | — | 87 | 10,500 | 1.65 |
| Synthesis Example 10 | A2-4 | — | — | M-3 | 78 | M-7 | 2 | — | — | M-10 | 20 | 50 | 9,000 | 1.7 |
| Synthesis Example 11 | A2-5 | — | — | M-4 | 98 | M-7 | 2 | — | — | — | — | 69 | 10,000 | 1.55 |

### <Preparation of Compositions for Forming a Liquid Immersion Upper Layer Film>

Other components other than the polymer using for preparation of the composition for forming a liquid immersion upper layer film will be shown as follows.

### Solvent (B)

B-1: 4-methyl-2-pentanol

B-2: diisoamyl ether

### Example 1

A composition for forming a liquid immersion upper layer film was prepared by blending 80 parts by mass of (A1-1) as a polymer (A1), 20 parts by mass of (A2-1) as a polymer (A2), and 3,730 parts by mass of (B-1) and 932 parts by mass of (B-2) as a solvent (B).

### Examples 2 to 24 and Comparative Examples 1 and 2

Each composition for forming a liquid immersion upper layer film was synthesized by operating similar to Synthesis Example 1, provided that the type and the amount (parts by mass) of blended monomers were as described in Table 2. It is to be noted that “-” in Table 2 shows that the corresponding monomer was not blended.

TABLE 2

| | Polymer (A1) | | Polymer (A2) | | | | Solvent (B) | |
|---|---|---|---|---|---|---|---|---|
| | type | parts by mass | type | parts by mass | type | parts by mass | type | parts by mass |
| Example 1 | A1-1 | 80 | A2-1 | 20 | — | — | B-1/B-2 | 3,730/932 |
| Example 2 | A1-1 | 90 | A2-2 | 10 | — | — | B-1/B-2 | 3,730/932 |
| Example 3 | A1-1 | 95 | A2-3 | 5 | — | — | B-1/B-2 | 3,730/932 |
| Example 4 | A1-1 | 20 | A2-1 | 20 | A2-5 | 60 | B-1/B-2 | 3,730/932 |
| Example 5 | A1-1 | 10 | A2-2 | 10 | A2-5 | 80 | B-1/B-2 | 3,730/932 |
| Example 6 | A1-1 | 5 | A2-3 | 5 | A2-5 | 90 | B-1/B-2 | 3,730/932 |
| Example 7 | A1-2 | 80 | A2-1 | 20 | — | — | B-1/B-2 | 3,730/932 |
| Example 8 | A1-2 | 90 | A2-2 | 10 | — | — | B-1/B-2 | 3,730/932 |
| Example 9 | A1-2 | 95 | A2-3 | 5 | — | — | B-1/B-2 | 3,730/932 |
| Example 10 | A1-3 | 80 | A2-1 | 20 | — | — | B-1/B-2 | 3,730/932 |
| Example 11 | A1-3 | 90 | A2-2 | 10 | — | — | B-1/B-2 | 3,730/932 |
| Example 12 | A1-3 | 95 | A2-3 | 5 | — | — | B-1/B-2 | 3,730/932 |
| Example 13 | A1-4 | 80 | A2-1 | 20 | — | — | B-1/B-2 | 3,730/932 |
| Example 14 | A1-4 | 90 | A2-2 | 10 | — | — | B-1/B-2 | 3,730/932 |
| Example 15 | A1-4 | 95 | A2-3 | 5 | — | — | B-1/B-2 | 3,730/932 |
| Example 16 | A1-5 | 80 | A2-1 | 20 | — | — | B-1/B-2 | 3,730/932 |
| Example 17 | A1-5 | 90 | A2-2 | 10 | — | — | B-1/B-2 | 3,730/932 |
| Example 18 | A1-5 | 95 | A2-3 | 5 | — | — | B-1/B-2 | 3,730/932 |
| Example 19 | A1-6 | 80 | A2-1 | 20 | — | — | B-1/B-2 | 3,730/932 |
| Example 20 | A1-6 | 90 | A2-2 | 10 | — | — | B-1/B-2 | 3,730/932 |
| Example 21 | A1-6 | 95 | A2-3 | 5 | — | — | B-1/B-2 | 3,730/932 |
| Example 22 | A1-6 | 20 | A2-1 | 20 | A2-5 | 60 | B-1/B-2 | 3,730/932 |
| Example 23 | A1-6 | 10 | A2-2 | 10 | A2-5 | 80 | B-1/B-2 | 3,730/932 |
| Example 24 | A1-6 | 5 | A2-3 | 5 | A2-5 | 90 | B-1/B-2 | 3,730/932 |
| Comparative Example 1 | — | — | A2-1 | 20 | A2-4 | 80 | B-1/B-2 | 3,730/932 |
| Comparative Example 2 | — | — | A2-1 | 20 | A2-5 | 80 | B-1/B-2 | 3,730/932 |

### <Synthesis of Polymer Contained in the Resist Composition>

Each polymer contained in the resist composition was synthesized by using each monomer represented by the following formulae (M-11) to (M-13).

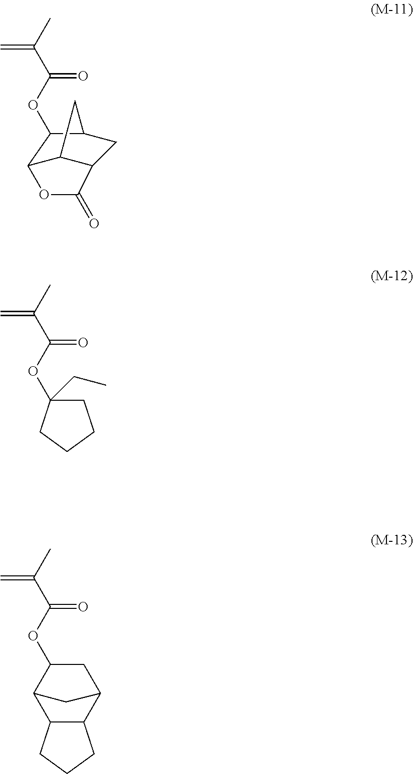

### Synthesis Example 12

To 500 mL flask were charged 47.54 g (46 mol %) of (M-11), 12.53 g (15 mol %) of (M-12), 39.93 g (39 mol %) of (M-13), 4.08 g of dimethyl 2,2′-azobis(2-methylpropionate) and 200 g of 2-butanone, and a polymerizing reaction was performed at 80° C. for 6 hours in a nitrogen atmosphere. After completion of the polymerization, the polymer solution was cooled with water to 30° C. or less, and charged into 2,000 g of methanol to precipitate a polymer. After filtering off the polymer, the polymer was washed by adding 800 g of methanol. After further filtering off the polymer, the polymer was dried at 50° C. for 17 hours to obtain a polymer (P-1) (73 g, yield: 73%). This polymer had an Mw of 5,700, and an Mw/Mn of 1.7. Also, the result of ¹³C-NMR analysis showed that the polymer was a copolymer having the contents of the structural units derived from (M-11), (M-12), and (M-13) being 51.4 mol %, 14.6 mol %, and 34.0 mol %, respectively.

### <Preparation of the Resist Composition>

To a mixture of 100 parts by mass of (P-1) as a polymer, 1.5 parts by mass of triphenylsulfonium nonafluoro-n-butane sulfonate and 6 parts by mass of 1-(4-n-butoxynaphthalene-1-yl)tetrahydrothiophenium nonafluoro-n-butane sulfonate as an acid generating agent, and 0.65 parts by mass of R-(+)-(tert-butoxycarbonyl)-2-piperidine methanol as an acid diffusion control agent were added 2,900 parts by mass of propylene glycol monomethyl ether acetate, 1,250 parts by mass of cyclohexanone, and 100 parts by mass of γ-butyrolactone as a solvent to adjust the solid content concentration of 5% by mass, and then filtered by a filter having a pore size of 30 nm to prepare a resist composition.

### <Evaluation>

The water repellency, anti-eluting properties, solubility, peel resistance and exposure latitude were evaluated, and the results are shown in Table 3.

### [Water Repellency]

Each composition for forming a liquid immersion upper layer film was spin coated on the silicon wafer, and PB was carried out at 90° C. for 60 sec to form a liquid immersion upper layer film having a film thickness of 30 nm. Thereafter, the wafer was placed on the receding contact angle measuring apparatus (DSA-10, manufactured by KRUS), discharged water through a syringe on the wafer to form 25 μL of water droplet on the wafer, withdrew the syringe from the water droplet, and then re-inserted the syringe in the water droplet, measured the receding contact angle at a frequency of 1 time per second while suctioning the water droplet through the syringe at a speed of 10 μL/min for 90 sec. Then, the receding contact angles measured within 20 sec after the measurement was stabilized were averaged. When the measurement value is no less than 75°, the water repellency is regarded as particularly favorable “AA”. When the value was no less than 70° and less than 75°, the water repellency was regarded as favorable “A”. When the value was less than 70°, the water repellency was regarded as unfavorable “B”.

### [Anti-Eluting Properties]

A silicone rubber whose central part was hollowed out was put on the silicon wafer, and filled the hollowed part with 10 mL of ultra pure water. Then, other silicon wafer, in which the resist film and liquid immersion upper layer film was formed, was stacked on the above silicon wafer so as to contact the liquid immersion upper layer film with ultra pure water. Also, the resist film was formed by spin coating the wafer with the resist composition, and then baking the composition at 115° C. for 60 sec (the film thickness was 205 nm). Also, the liquid immersion upper layer film was formed by spin coating the resist film with each composition for forming a liquid immersion upper layer film, and then baking the composition at 90° C. for 60 sec (the film thickness was 30 nm).

After contacting the liquid immersion upper layer film with ultra pure water for 10 sec, the other silicon wafer was removed, and the ultra pure water was recovered, and the eluting amount of the acid generating agent and acid diffusion control agent dissolved in pure water was measured by LC mass spectrometer (LC part: SERIES1100 from AGILENT, MS part: Mariner from Perseptive Biosystems, Inc.). Also, the measurement was carried out by using a column (CAPCELL PAK MG, from SHISEIDO) at a temperature for measurement of 35° C., flow rate of 0.2 mL/min, and using water/methanol (3/7) with 0.1% by mass of formic acid as an eluting solvent. In the case, when the eluting amount of the acid generating agent and acid diffusion control agent are both less than 5.0×10⁻¹² mol/cm², the anti-eluting properties was regarded as favorable “A”. When the eluting amount of the acid generating agent and acid diffusion control agent are either over 5.0×10⁻¹² mol/cm², the properties was regarded as unfavorable “B”.

### [Solubility]

Each composition for forming a liquid immersion upper layer film was spin coated on the silicon wafer and PB was carried out at 90° C. for 60 sec to form a liquid immersion upper layer film having a film thickness of 90 nm. Puddle development was carried out by 2.38% by mass TMAH aqueous solution for 60 sec. After drying, the surface of the wafer was observed, and the result was regarded as solubility. In the case, when there are no residues, solubility was regarded as favorable “A”. When residues were observed, solubility was regarded as unfavorable “B”.

### [Peel Resistance]

Each resist composition was spin coated on the silicon wafer without treating with HMDS (hexamethyldisilazane) and PB was carried out at 100° C. for 60 sec to form a resist film having a film thickness of 100 nm. Then, each composition for forming a liquid immersion upper layer film was spin coated on the resist film, and PB was carried out at 90° C. for 60 sec to form a liquid immersion upper layer film having a film thickness of 30 nm. After that, the film was rinsed with pure water for 60 sec using an apparatus for producing semiconductors (CLEAN TRACK ACT8, manufactured by Tokyo Electron Ltd.), and then dried. Thereafter, the presence of peering of the liquid immersion upper layer film was visually observed, the result was regarded as peel resistance. In the case, when any peering was not observed, peel resistance was regarded as favorable “A”. When peering was observed, peel resistance was regarded as unfavorable “B”.

### [Exposure Latitude]

Each resist composition was spin coated on the silicon wafer and PB was carried out at 100° C. for 60 sec to form a resist film having a film thickness of 100 nm. Then, each composition for forming a liquid immersion upper layer film was spin coated on the resist film, and PB was carried out at 90° C. for 60 sec to form a liquid immersion upper layer film having a film thickness of 30 nm. Then liquid immersion lithography of the film was performed by ultra pure water (liquid immersion medium) using Immersion Scanner (S610C, manufactured by Nikon) and a mask for forming 1:1 line-and-space having a line width of 50 nm, and then the film was developed with 2.38% by mass TMAH aqueous solution at 25° C. for 60 sec, washed with water, and dried to form a resist pattern. At this time, the exposure dose in which the line width is within ±10% of the designed dimension was measured, and the ratio of the exposure dose to the optimum exposure dose (the exposure dose in which 1:1 line-and-space having a line width of 50 nm is formed) was calculated, and the ratio was regarded as exposure latitude. Also, the line width was measured by using a scanning electron microscope (S9260A, manufactured by Hitachi High-Technologies Corporation). In the case, when the ratio is no less than 15%, exposure latitude was regarded as favorable “A”, when the ratio is less than 15%, regarded as unfavorable “B”.

TABLE 3

| | | Anti- | | | |
|---|---|---|---|---|---|
| | Water | eluting | | Peel | Exposure |
| | repellency | properties | Solubility | resistance | latitude |
| Example 1 | A | A | A | A | A |
| Example 2 | A | A | A | A | A |
| Example 3 | A | A | A | A | A |
| Example 4 | AA | A | A | A | A |
| Example 5 | AA | A | A | A | A |
| Example 6 | AA | A | A | A | A |
| Example 7 | A | A | A | A | A |
| Example 8 | A | A | A | A | A |
| Example 9 | A | A | A | A | A |
| Example 10 | A | A | A | A | A |
| Example 11 | A | A | A | A | A |
| Example 12 | A | A | A | A | A |
| Example 13 | A | A | A | A | A |
| Example 14 | A | A | A | A | A |
| Example 15 | A | A | A | A | A |
| Example 16 | A | A | A | A | A |
| Example 17 | A | A | A | A | A |
| Example 18 | A | A | A | A | A |
| Example 19 | A | A | A | A | A |
| Example 20 | A | A | A | A | A |
| Example 21 | A | A | A | A | A |
| Example 22 | AA | A | A | A | A |
| Example 23 | AA | A | A | A | A |
| Example 24 | AA | A | A | A | A |
| Comparative | A | A | A | A | B |
| Example 1 | | | | | |
| Comparative | AA | A | A | B | A |
| Example 2 | | | | | |

As shown in the result of Table 3, water repellency, anti-eluting properties and solubility were favorable in both of Examples and Comparative Examples. In contrast, peel resistance and exposure latitude was either unfavorable in Comparative Examples, while both were favorable in Examples.

The embodiments of the present invention can provide a composition for forming a liquid immersion upper layer film capable of balancing peel resistance with exposure latitude while meeting characteristics of water repellency, anti-eluting properties and solubility, and a method for forming a resist pattern. Therefore, the composition for forming a liquid immersion upper layer film and method for forming a resist pattern can be suitably applied to a process of making semiconductor devices having further miniaturized resist patterns.

Obviously, numerous modifications and variations of the present invention are possible in light of the above teachings. It is therefore to be understood that within the scope of the appended claims, the invention may be practiced otherwise than as specifically described herein.

What is claimed is:

1. A composition for forming a liquid immersion upper layer film, comprising:
a first polymer including a first structural unit having a group represented by a following formula (i):
—R¹OH)ₙ (i)
wherein, in the formula (i), n is an integer of 1 to 3, and R¹ represents a hydrocarbon group having a valency of (n+1) and having 1 to 20 carbon atoms;
a second polymer that is different from the first polymer; and
a solvent.

2. The composition for forming a liquid immersion upper layer film according to claim 1, wherein a receding contact angle of the second polymer in a form of film on water is greater than a receding contact angle of the first polymer in a form of film on water.

3. The composition for forming a liquid immersion upper layer film according to claim 1, wherein the first structural unit is represented by a following formula (1): 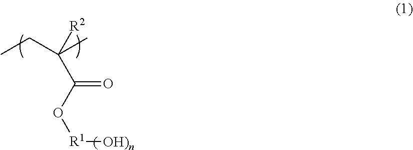
wherein, in the formula (1), R¹ and n are as defined in the formula (i); and R² represents a hydrogen atom, a methyl group, a fluorine atom or a trifluoromethyl group.

4. The composition for forming a liquid immersion upper layer film according to claim 1, wherein the second polymer includes a structural unit having a group represented by a following formula (2), a structural unit having a group represented by a following formula (3), or a combination thereof: 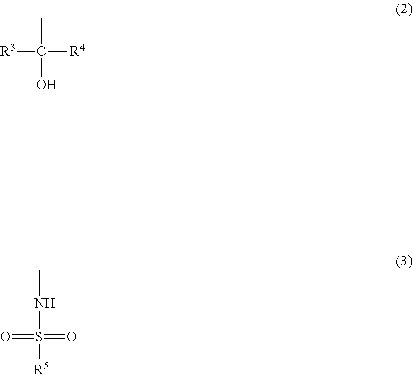
wherein, in the formula (2), each of R³ and R⁴ represents a hydrogen atom, an alkyl group having 1 to 4 carbon atoms or a fluorinated alkyl group having 1 to 4 carbon atoms, wherein at least one of R³ and R⁴ represents a fluorinated alkyl group having 1 to 4 carbon atoms, and
in the formula (3), R⁵ represents a fluorinated alkyl group having 1 to 20 carbon atoms.

5. The composition for forming a liquid immersion upper layer film according to claim 1, wherein the second polymer further includes a third structural unit represented by a following formula (4): 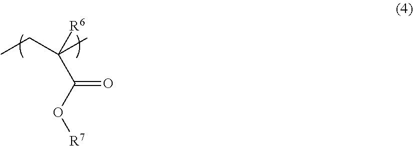
wherein, in the formula (4), R⁶ represents a hydrogen atom, a methyl group, a fluorine atom or a trifluoromethyl group; and R⁷ represents a monovalent fluorinated hydrocarbon group having 1 to 12 carbon atoms.

6. The composition for forming a liquid immersion upper layer film according to claim 1, wherein the first polymer further includes a structural unit having a group represented by a following formula (2′), a structural unit having a group represented by a following formula (3′), or a combination thereof: 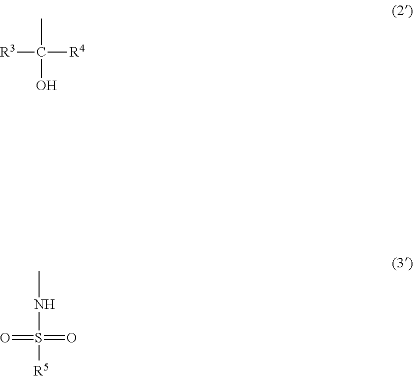
wherein, in the formula (2′), each of R³ and R⁴ represents a hydrogen atom, an alkyl group having 1 to 4 carbon atoms or a fluorinated alkyl group having 1 to 4 carbon atoms, wherein at least one of R³ and R⁴ represents a fluorinated alkyl group having 1 to 4 carbon atoms, and
in the formula (3′), R⁵ represents a fluorinated alkyl group having 1 to 20 carbon atoms.

7. The composition for forming a liquid immersion upper layer film according to claim 1, wherein the first polymer further includes a fourth structural unit having a sulpho group.

8. The composition for forming a liquid immersion upper layer film according to claim 1, wherein the solvent comprises an ether solvent.

9. A method for forming a resist pattern, comprising:
providing a resist film on a substrate using a resist composition;
providing a liquid immersion upper layer film on the resist film using the composition for forming a liquid immersion upper layer film according to claim 1;
exposing the resist film and the liquid immersion upper layer film through a liquid immersion medium; and
developing the resist film and the liquid immersion upper layer film exposed.
